(19) United States
(12) Patent Application Publication
(10) Pub. No.: US 2009/0244858 A1
(43) Pub. Date: Oct. 1, 2009

(54) IC CARD HAVING IMPROVED ELECTRICAL CONTACTS

(75) Inventors: Giovanni Di Sirio, Salerno (IT); Giovanni Fontana, Napoli (IT)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: INCARD S.A., Geneva (CH)

(21) Appl. No.: 12/415,111

(22) Filed: Mar. 31, 2009

(30) Foreign Application Priority Data
Mar. 31, 2008 (IT) MI2008A000543

(51) Int. Cl. H05K 1/18

(52) U.S. Cl. 361/748

(57) ABSTRACT

An IC Card includes a microchip having memory portions storing programs and a plurality of electrical contacts including a first set of electrical contacts connected to the microchip for supporting respective and predetermined functions, according to a predetermined ISO 7816 standard that reserves a second set of the electrical contacts for future use. At least one electrical contact of the second set is further connected to the microchip and is configured by one or more of the programs for supporting respective additional functions.

### FIELD OF THE INVENTION

The present invention relates to the field of IC Cards, and, more particularly, to an IC Card having electrical contacts for cooperation with another device.

### BACKGROUND OF THE INVENTION

An IC Card comprises a microchip and a plurality of electrical contacts. The microchip comprises memory portions, for example a ROM and an EEPROM, storing data and programs. The electrical contacts are wired on the microchip so that an external device, connected to the electrical contacts, may access the memory portions for data transmission or programs execution.

For example, with reference to FIG. 1, it is represented an IC Card 1 including a microchip 2 and electrical contacts c1, c2, c3, c4, c5, c6, c7, c8. The electrical contacts c1, c2, c3, c4, c5, c6, c7, c8 support respective and predetermined functions, according to an ISO 7816 also standard, defining their dimensions, location and number.

More particularly, the ISO 7816 standard provides that a first set s1 of contacts, comprising the electrical contacts c1, c2, c3, c5, c6, c7, is electrical connected to the microchip 2 while a second set s2 of contacts, comprising the electrical contacts c4 and c8, is reserved for future use.

The contact C1 is also known as Vcc Power connection and is the contact through which operating power is supplied to the microchip 2. The contact C2, also referred as RST Reset line, is the contact through which the external device signals to the microchip 2 to initiate a reset sequence of instructions, such instructions being for example stored in the ROM of the IC Card 1.

The contact C3 or CLK Clock signal is the contact through which a clock signal is provided to the microchip 2. It controls the operation speed and provides a common framework for data communication between the external device and the IC Card. The contact C4 is referred as RFU or Reserved for future use because is unused; it is not associated to a specific function from the standard ISO 7816.

The contact C5, also known as GND Ground line, provides a common electrical ground between the external device and the IC Card 1. The C6 contact or Vpp Programming power connection is provided to program the EEPROM of some IC Card.

The C7 contact or I/O Input/output line provides a half-duplex communication channel between the external device and the IC Card. The contact C8 is referred as RFU Reserved for future use as the C4 contact because it is unused.

As it is apparent from the previous description, the electrical contacts c1, c2, c3, c5, c6, c7 of the first set s1 substantially provides the minimum set of electrical functions for enabling the IC Card 1 to work. Each electrical contact of the first set s1 is reserved to the respective predetermined function, without which the IC Card 1 cannot work.

For example, if no power is provided through the c1 electrical contact, the IC Card 1 is powered off or, if the c7 electrical contact does not implement the I/=channel, the IC Card 1 is unable to communicate with the external device. It is also known that some IC Cards provides that one or both the electrical contacts c4 and/or c8 are connected to the microchip 2, in order to implement additional functions, not provided by the ISO 7816 standard.

In other words, one or both the electrical contacts c4 and c8 allow the microchip 2 to receive and/or transmit from/to the external device a specific electronic signal, implementing an additional function. In this case, the microchip 2 and the external device are specifically designed to detect such electronic signal and execute the corresponding additional function. Even if such IC Cards allow to exploit the available resources of the IC Card 1, they suffer for the problem that the c4 and c8 electrical contacts are reserved for the implementation of the corresponding additional functions.

For example, both the c4 and c8 electrical contacts may be used for implementing respective I/O channels for the pre-personalization phase of the IC Card 1, in order to increase the throughput of the data transmission from an initialization device to the IC Card, during pre-personalization. This is advantageous for the pre-personalization phase, since it requires a high speed for data transmission from the initialization device to the IC Card, due to a great amount of data to be transferred.

However, after the pre-personalization phase, the electrical contacts c4 and c8 are substantially unusable for other functions, because they are reserved and limited to the input/output additional functions provided for the pre-personalization phase. In other words, it may not be possible to use the c4 and c8 electrical contacts for another phase, for example for a user phase, and for implementing different function. More particularly, during the user phase, the security of data may be more important than the speed of the data transmission; so it would be preferable to implement a security additional function for the c4 and/or c8 electrical contact instead of the input/output additional function already implemented for the pre-personalization phase.

### SUMMARY OF THE INVENTION

The present disclosure provides an IC Card with a set of electrical contacts that, according to the ISO 7816, are reserved for future use, are connected to the microchip of the IC Card for implementing a plurality of additional functions, overcoming the limitation that allows implementing only one predetermined function for a respective electrical contact.

The approach on which the present invention is based, is that of connecting at least one electrical contact of a set of (reserved for future use) RSU electrical contacts, to a microchip of the IC Card and storing, inside the memory portions of the microchip, one or more programs for configuring such at least one electrical contact and enabling it to support a respective additional function. Depending on the program executed, the at least one electrical contact implements a specific additional function so that it may be used for different purposes.

According to this idea, the IC Card comprises a microchip including memory portions storing programs and a plurality of electrical contacts including a first set of electrical contacts connected to the microchip for supporting respective and predetermined functions, according to a predetermined ISO 7816 standard that reserves a second set of the electrical contacts for future use. At least one electrical contact of the second set is further connected to the microchip and is configured by one or more of the programs for supporting respective additional functions.

An aspect is directed to a method for connecting a microchip of an IC Card, including memory portions storing programs to a plurality of electrical contacts of the IC Card, including a first set of electrical contacts connected to the microchip for supporting respective and predetermined functions according to a predetermined ISO 7816 standard that reserves a second set of the electrical contacts for future use. The method includes connecting at least one electrical contact of the second set to the microchip and executing one or more of the programs for configuring the at least one electrical contact in order to support a respective additional function.

Advantageously, one or more of the electrical contact that are reserved for future use, according to the standard ISO 7816, are connected to the microchip and configured by the programs of the IC Card to be used for implement additional functions.

Advantageously, a program of the IC Card may configure one or both the electrical contacts of the second set for supporting a function specifically useful during a certain phase of the IC Card, for example for increasing the throughput of the transmission of data during the pre-personalization phase or for improving the security during the user phase.

Advantageously, two or more programs of the IC Card may configure one or both the electrical contacts of the second set for supporting two or more different functions during a same phase of the IC Card, for example configuring one or both the electronic contacts only for input functions, when a specific applet is executed during the user phase, and configuring them only for output, when another applet is executed during the same user phase.

Advantageously, according to the IC Card and the method of the invention, the communication between the microchip of the IC Card and the external device intended to communicate with it, is flexible and configurable.

Further characteristics and the advantages of the IC Card and the method according to the present invention will be apparent from the following description of an embodiment thereof, made with reference to the annexed drawings, given for indicative and non-limiting purpose.

### BRIEF DESCRIPTION OF THE DRAWINGS

FIG. 1 schematically shows an IC Card including a microchip connected to a plurality of electrical contacts, according to the prior art;

FIG. 2 schematically shows an IC Card including a microchip connected to a plurality of electrical contacts, according to the present invention;

FIG. 3 schematically shows a microchip of the IC Card of FIG. 2 including a plurality of programs, according to the present invention;

FIG. 4 schematically shows a couple of electrical contacts connected to the microchip of FIG. 3.

### DETAILED DESCRIPTION OF THE PREFERRED EMBODIMENTS

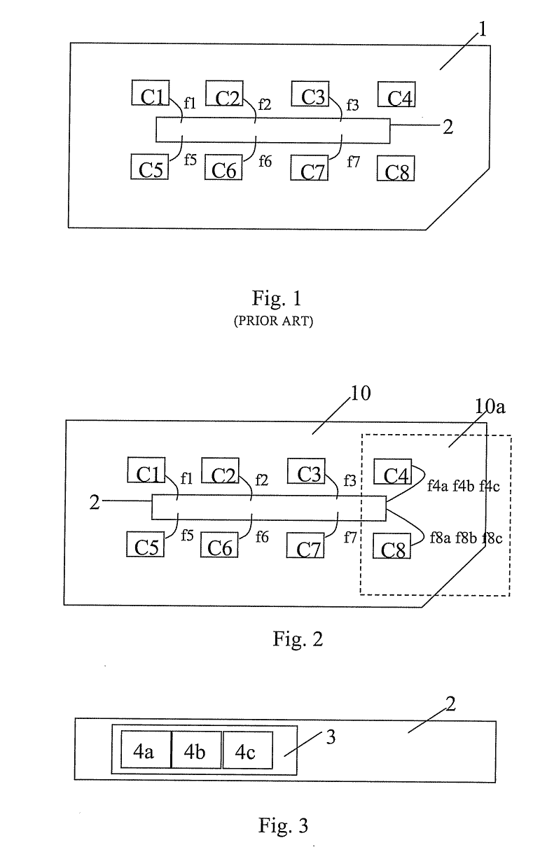

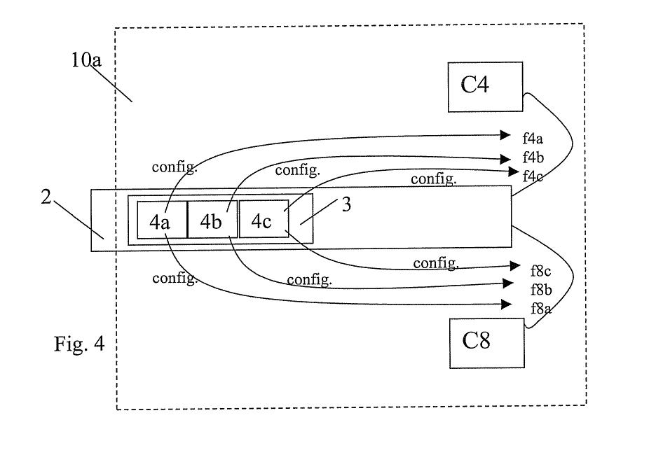

With reference to FIG. 2, an IC Card schematically represented and indicated with numeral reference 10 comprises a plurality of electrical contacts c1, c2, c3, c4, c5, c6, c7, c8 and a microchip 2. The microchip 2 comprises one or more memory portion 3, for example a ROM and an EEPROM which stores programs 4a, 4b, 4c, as schematically represented in FIG. 3.

The electrical contacts c1, c2, c3, c4, c5, c6, c7, c8 support respective and predetermined functions, according to an ISO 7816 standard, defining also their dimensions, location and number. More particularly, a first set s1 of contacts comprises the electrical contacts c1, c2, c3, c5, c6, c7, connected to the microchip 2 for supporting respective and predetermined functions f1, f2, f3, f5, f6, f7, according to the ISO 7816 standard. Such standard reserves a second set s2 of contacts, including the electrical contacts c4, c8, for future use.

At least one electrical contact c4 of the second set s2 is further connected to the microchip 2 and is configured by one or more of the programs 4a, 4b, 4c for supporting respective additional functions f4a, f4b, f4c. One or more of the additional functions f4a, f4b, f4c are associated to a respective state st1, st2, st3, st4 of the IC Card 1.

For example, state st1 may be a test state wherein the microcontroller and the memory portions of the microchip 2 are tested from a test device which connects the microchip 2 via the electrical contacts and transmits to the microchip 2 a plurality of test data. State st2 may be a pre-personalization state wherein pre-personalization data are transmitted from an initialization device to the IC Card. State st3 may be a personalization state wherein personal data are stored in the IC Card 1. State st4 is a final and user state wherein the IC Card 1 is already delivered to a user and it communicates with a terminal for executing applications.

At least one of the programs 4a, 4b, 4c is stored in a ROM of the microchip 2. In fact, during the test phase, the ROM is available, since the EEPROM has not been already initialized via the pre-personalization phase. A program in ROM is for configuring an additional function for one or both the electrical contacts c4, c8, for example configuring the c4 electrical contact as input channel and the c8 electrical contact as output channel, in order to improve the communication with the test device.

When the test phase of the IC Card 1 is terminated, the EEPROM may be initialized, executing a copy of data and programs stored in a memory of a base IC Card, used as a model. Since the initialization of the EEPROM usually involves intensive input operations, due to the transmission of the content of the memory of the base IC Card to a plurality of IC Cards to be initialized, a program in ROM provides the configuration the c4 and c8 electrical contacts for input functions only. Advantageously, the c4 and c8 electrical contacts are input channel additional to the c7 electrical contact so that the time involved for the initialization of the EEPROM is noticeably reduced.

In other words, the one or both the electrical contact c4 and c8 may be configured for different functions f4a, f4b, f4c from different programs 4a, 4b, 4c of the ROM. With reference to the example given above, a first program 4a configures the c4 contact for a function f4a of input and the c8 contact for a function f4b output, while a second program 4b configures both the c4 and c8 contacts for the function f4a of input.

At least one of the programs in the EEPROM of the IC Card 1 is a program 4a, 4b, 4c for further configuring the electrical contact c4 and c8 of the second set s2. As explained with reference to the description above, also the electrical contact c4 may be configured for a different function f4a, f4b, f4c from a different program 4a, 4b, 4c of the EEPROM.

One or both the electrical contacts c4, c8 of the second set s2 are further connected to the microchip 2 and configured by the programs 4a, 4b, 4c for supporting respective additional functions f4a, f4b, f4c; f8a, f8b, f8c.

More particularly, the electrical contacts c8 may be configured for supporting an additional function f8a, different from the additional function f4a supported by the other electrical contacts c4 or it may be configured for supporting a same additional function.

An aspect relates to a method for connecting a microchip 2 of an IC Card 1, including a memory portions 3 storing programs 4a, 4b, 4c, to a plurality of electrical contacts c1, c2, c3, c4, c5, c6, c7, c8 of the IC Card 1.

A first set s1 of the contacts comprises electrical contacts c1, c2, c3, c5, c6, c7 connected to the microchip 2, for supporting respective and predetermined functions f1, f2, f3, f5, f6, f7, according to a predetermined ISO 7816 standard that reserves a second set s2 of contacts for future use. The second set s2 of contacts comprises the electrical contacts c4, c8.

The method provides a phase for connecting at least one electrical contact c4 of the second set s2 to the microchip 2 and a phase for executing one or more of the programs 4a, 4b, 4c for configuring the at least one electrical contact c4. The configuration of the electrical contact c4 provides that the electrical connection between the electrical contact c4 and the microchip supports an additional function f4a, f4b, f4c. The additional function may be one of the functions defined by the ISO 7816 with reference to the first set s1 of electrical contacts c1, c2, c3, c5, c6, c7.

According to the method, both the electrical contact c4 and c8 of the second set s2 may be connected to the microchip 2 and the programs 4a, 4b, 4c executed for configuring both the electrical contacts c4 and c8, in order to support respective additional functions f4a, f4b, f4c, f8a, f8b, f8c.

Advantageously, the IC Card avoids limiting electrical contacts c4 and c8 for a single predetermined use. In fact, the computer executable software stored inside the IC Card provides that c4 and c8 electrical contacts, hard wired to the microchip, may receive and transmit a different electric signal, to be used for a different function.

For example, when the IC Card is connected to a first external device, a first software stored in the IC Card and intended to manage a communication with the first device, configures the c4 and/or the c8 electrical contact for receiving a first electrical signal, implementing a function supported by such first device.

At the same time, when the IC Card is connected to a second external device, a second software stored in the IC Card and intended to manage a communication with the second device, configures the c4 and/or the c8 electrical contact for receiving a second electrical signal, implementing a function supported by such first device.

The first and second electrical signal may be different. For example, without limiting the scope of the present invention, the first signal may be a clock signal while the second signal may be an input signal. Both the first and the second signal may be supported by a same electrical contact, due to the execution of corresponding programs that configures the electrical contact.

Hereafter an embodiment is briefly reported. According to such embodiment, the second set s2 of electrical contacts c4 and c8 of the IC Card 1 are configured as input/output analogical electrical contacts c4 and c8. According to this embodiment, a digital file stored in a memory of the IC Card 1, for example an mp3 file, may be converted in analogical format, from a converter stored inside the IC Card 1 itself, and transmitted to the input/output analogical electrical contact c4 and c8 for reproduction.

More particularly, according to this embodiment, it is avoided a transmission of the digital file from the IC Card to the player, since the player is inside the IC Card itself. In fact the player is substantially substituted by the application inside the IC Card, enabled to execute the D(igital) to A(nalogical) conversion and to redirect the output of such conversion to the input/output analogical electrical contacts c4 and c8, for reproduction.

Advantageously, the mp3 file is kept secure inside the IC Card, for example in crypted format, and cannot be copied because it is converted inside the IC Card itself and directly transmitted to the input/output analogical electrical contacts c4 and c8. Moreover, the mp3 may be substantially heard through a simple reader provided only for power, clock signal, and earphones.

An IC card providing such input/output analogical electrical contacts c4 and c8 is also advantageous for the fact that it is portable and connectable to a plurality of reader device, rendering very easy to convert and reproduce the digital file, without compromising security. As already stated, the input output analogical electrical contacts c4 and c8, may be reconfigured for implementing a different function. For example, when an applet associated to the conversion of the mp3 file is stopped, another program may be executed for the reconfiguration of the c4 and c8 electrical contacts.

Advantageously, one or more of the electrical contacts that, according to the standard ISO 7816, are reserved for future use, are connected to the microchip and configured by the programs of the IC Card to be used for different functions. Advantageously, a program of the IC Card may configure one or both the electrical contacts of the second set for supporting a function specifically useful during a certain phase of the IC Card, for example for increasing the throughput of the transmission of data during the pre-personalization phase and for improving the security during the user phase.

Advantageously, two or more programs of the IC Card may configure one or both the electrical contacts of the second set for supporting two or more different functions during a same phase of the IC Card, for example configuring one or both the electronic contacts only for input when a specific applet is executed during the user phase and configuring them for output when another applet is executed during the user phase.

Advantageously, according to the IC Card and the method, the interaction between the microchip of the IC Card and an external device intended to communicate with it, is more flexible and configurable.

1-10. (canceled)

11. An IC Card comprising:
a microchip comprising a memory for storing at least one computer executable program; and
a plurality of electrical contacts including a first set of electrical contacts coupled to said microchip for supporting a plurality of functions according to an ISO 7816 standard and a second set of electrical contacts unused according to the ISO 7816 standard;
at least one electrical contact of the second set thereof being coupled to said microchip and being configurable based upon the at least one computer executable program for supporting at least one additional function.

12. An IC Card according to claim 11, wherein the at least one additional function is associated with a respective state of the IC Card.

13. An IC Card according to claim 11, wherein said memory comprises a read only memory (ROM).

14. An IC Card according to claim 13, wherein said ROM stores at least one additional program; and wherein at least one of said second set of electrical contacts is configurable by the at least one additional program.

15. An IC Card according to claim 11, wherein said memory comprises an electronically erasable programmable read only memory (EEPROM).

16. An IC Card according to claim 15, wherein said EEPROM stores at least one additional program; and wherein at least one of said second set of electrical contacts is configurable by the at least one additional program.

17. An IC Card according to claim 11, wherein each electrical contact of said second set thereof is coupled to said microchip and configurable based upon the at least one computer executable program for supporting at least one additional function.

18. An IC Card according to claim 17, wherein at least one electrical contact of said second set thereof is configurable based upon the at least one computer executable program for supporting an additional function different from the additional function supported by others of said second set of electrical contacts.

19. An IC Card according to claim 17, wherein at least two electrical contacts of said second set thereof are configurable based upon the at least one computer executable program for supporting a same additional function.

20. An IC Card comprising:
an IC Card substrate;
a memory carried by said IC Card substrate for storing at least one computer executable program;
a processor coupled to said memory for executing the at least one computer executable program;
a first set of electrical contacts carried by said IC card substrate and coupled to said memory for supporting at least one predetermined function; and
a second set of electrical contacts carried by said IC card substrate and coupled to said memory, at least one electrical contact of said second set thereof being configurable based upon said processor executing the at least one computer executable program for supporting at least one additional function.

21. An IC Card according to claim 20, wherein the at least one additional function is associated with a respective state of the IC Card.

22. An IC Card according to claim 20, wherein said memory comprises a read only memory (ROM).

23. An IC Card according to claim 22, wherein said ROM stores at least one additional computer executable program; and wherein at least one electrical contact of said second set thereof is configurable based upon said processor executing the at least one additional computer executable program.

24. An IC Card according to claim 20, wherein said memory comprises an electronically erasable programmable read only memory (EEPROM).

25. An IC Card according to claim 24, wherein said EEPROM stores at least one additional computer executable program; and wherein at least one electrical contact of said second set thereof is configurable based upon said processor executing the at least one additional computer executable program.

26. A method of connecting a microchip of an IC Card, comprising a memory for storing at least one program, to a plurality of electrical contacts of the IC Card, the plurality of electrical contacts including a first set of electrical contacts coupled to the microchip for supporting respective functions according to an ISO 7816 standard, and a second set of electrical contacts unused according to the ISO 7816 standard, the method comprising:
coupling at least one electrical contact of the second set thereof to the microchip; and
executing the at least one program to configure at least one electrical contact of the second set thereof for supporting at least one additional function.

27. A method according to claim 26, wherein the at least one additional function is associated with a respective state of the IC Card.

28. A method according to claim 26, wherein the memory comprises a read only memory (ROM).

29. A method according to claim 28, wherein the ROM stores at least one additional program; and wherein at least one electrical contact of the second set thereof is configurable based upon the at least one additional program.

30. A method to claim 26, wherein the memory comprises an electronically erasable programmable read only memory (EEPROM).

31. A method according to claim 30, wherein the EEPROM stores at least one additional program; and wherein at least one electrical contact of the second set thereof is configurable based upon the at least one additional program.

32. A method of making an IC Card comprising:
positioning a memory on an IC Card substrate for storing at least one computer executable program;
coupling a processor to the memory for executing the at least one computer executable program;
coupling a first set of electrical contacts to the memory for supporting at least one function; and
coupling a second set of electrical contacts to the memory, at least one electrical contact of the second set thereof being configurable based upon the processor executing the at least one computer executable program for supporting at least one additional function.

33. A method according to claim 32, wherein the at least one additional function is associated with a respective state of the IC Card.

34. A method according to claim 32, wherein the memory comprises a read only memory (ROM).

35. A method according to claim 34, wherein the ROM stores at least one additional computer executable program; and wherein at least one electrical contact of the second set thereof is configurable based upon the processor executing the at least one additional computer executable program.

36. A method to claim 32, wherein the memory comprises an electronically erasable programmable read only memory (EEPROM).

37. A method according to claim 36, wherein the EEPROM stores at least one additional computer executable program; and wherein at least one electrical contact of the second set thereof is configurable based upon the processor executing the at least one additional computer executable program.

38. A method according to claim 32, wherein each electrical contact of the second set thereof is configurable based upon the processor executing the at least one computer executable program for supporting a respective additional function.
